(19) United States
(12) Patent Application Publication
(10) Pub. No.: US 2005/0163247 A1
(43) Pub. Date: Jul. 28, 2005

(54) Isolation barrier for interfacing a line side device to a system side device

(75) Inventors: Michael Vlasov, Irvine, CA (US); Richard A. Ward, Laguna Niguel, CA (US); Karen D. Guthrie, Laguna Beach, CA (US)

Correspondence Address: FARJAMI & FARJAMI LLP, 26522 LA ALAMEDA AVENUE, SUITE 360, MISSION VIEJO, CA, 92691, US

(73) Assignee: Conexant Systems, Inc.

(21) Appl. No.: 10/758,458

(22) Filed: Jan. 15, 2004

(51) Int. Cl. H03K 19/0175; H04L 27/04; H04L 27/02; H03C 1/52; H03C 5/00

(52) U.S. Cl. 375/268; 375/300; 326/82

(57) ABSTRACT

According to one embodiment, an isolation barrier comprises a transformer and a controlled impedance module. The system side device generates an amplitude modulated clock signal when the system side device is in a transmit mode, and generates an unmodulated clock signal when the system side device is in a receive mode. When the system side device is in the receive mode, the controlled impedance module modulates, according to the data being transmitted by the line side device, the unmodulated clock signal incoming from the system side device. The transformer is utilized in bidirectional data transfer to provide the line side device with the amplitude modulated clock signal generated by the system side device, while providing the system side device with the amplitude modulated clock signal generated by the controlled impedance module and the line side device.

### BACKGROUND OF THE INVENTION

1. Field of the Invention

The present invention is generally directed to the field of telecommunications devices. More particularly, the present invention is in the field of interfacing a line side device to a system side device in a telecommunications device.

2. Related Art

A digital isolation barrier (“DIB”), also referred to as an “isolation barrier” in the present application, is commonly used between a line side device and a system side device in a telecommunications device, such as a modem. Typical digital isolation barriers comprise a transformer and capacitors where the transformer is utilized for providing power and clock from the system side device to the line side device and where the capacitors are used for bidirectional data transfer between the system side device and line side device. There are various problems with the conventional isolation barriers. By way of example, when the voltage between system side ground and line side ground increases during operation, for example due to noise or power fluctuations, the voltage across the capacitors can exceed maximum voltage ratings such that the data transferred via the DIB becomes corrupted. Thus, conventional isolation barriers suffer from performance and low data integrity issues due to, for example, noise and power fluctuations on the line side. As another example, the capacitors used in conventional isolation barriers require high voltage ratings and are expensive. Moreover, because the capacitors must have small capacitance, of approximately 10 pico farads for example, any additional parasitic capacitance will have significant detrimental effect and will significantly and undesirably add to the total capacitance. As such, in order to limit the magnitude of additional parasitic capacitance, the length of the lines connecting the system side to the line side must be severely limited, for example, to about three inches, which results in lack of flexibility in the design of any system using a data access arrangement (“DAA”) with the conventional isolation barrier.

Different attempts to solve the various problems of conventional isolation barriers have been unsuccessful. For example, a solution to reducing capacitor saturation and data corruption was to replace the capacitors in the isolation barrier by a second transformer. However, the addition of a second transformer to replace the capacitors in the data path adds to the complexity and expense of the system as well as causing electromagnetic interference. Thus, there is need in the art for a cost effective solution to various problems, such as the ones mentioned above, existing in the conventional digital isolation barriers.

### SUMMARY OF THE INVENTION

The present invention is directed to an isolation barrier for interfacing a line side device to a system side device. According to the present invention, instead of capacitors for data transfer and a transformer for power and clock, a single transformer is used for bi-directional data transfer between the system side device and the line side device, and for supplying clock and power. As such, noise and ground voltage surges occurring in the line side device are substantially prevented from passing through to the system side device. Furthermore, receiver saturation and data corruption do not occur. Moreover, the need for expensive capacitors having high voltage ratings is eliminated, and production costs are reduced. Further, the line side device can be placed at a substantially greater distance away from the system side device, since the concern about adding to the capacitance of the data transfer capacitors is eliminated (because capacitors are no longer part of the data transfer mechanism). As such, systems based on the invention's isolation barrier can be designed with increased flexibility.

According to the present invention, the isolation barrier comprises a transformer and a controlled impedance module. The system side device generates an amplitude modulated clock signal when the system side device is in a transmit mode, and generates an unmodulated clock signal when the system side device is in a receive mode. When the system side device is in the receive mode, the controlled impedance module modulates, according to the data being transmitted by the line side device, the unmodulated clock signal incoming from the system side device.

The transformer is utilized in bi-directional data transfer to provide the line side device with the amplitude modulated clock signal generated by the system side device when the system side device is in the transmit mode, while providing the system side device with the amplitude modulated clock signal generated by the controlled impedance module and the line side device when the system side device is in the receive mode. Other features and advantages of the present invention will become more readily apparent to those of ordinary skill in the art after reviewing the following detailed description and accompanying drawings.

### BRIEF DESCRIPTION OF THE DRAWINGS

FIG. 1 is a block diagram of an exemplary conventional isolation barrier coupled between a system side device and a line side device in a modem.

FIG. 2 is a block diagram of an embodiment of the invention's isolation barrier coupled between a system side device and a line side device in a modem.

### DETAILED DESCRIPTION OF THE INVENTION

The present invention is directed to an isolation barrier for interfacing a line side device to a system side device. The following description contains specific information pertaining to the implementation of the present invention. One skilled in the art will recognize that the present invention may be implemented in a manner different from that specifically discussed in the present application. Moreover, some of the specific details of the invention are not discussed in order not to obscure the invention.

The drawings in the present application and their accompanying detailed description are directed to merely exemplary embodiments of the invention. To maintain brevity, other embodiments of the present invention are not specifically described in the present application and are not specifically illustrated by the present drawings.

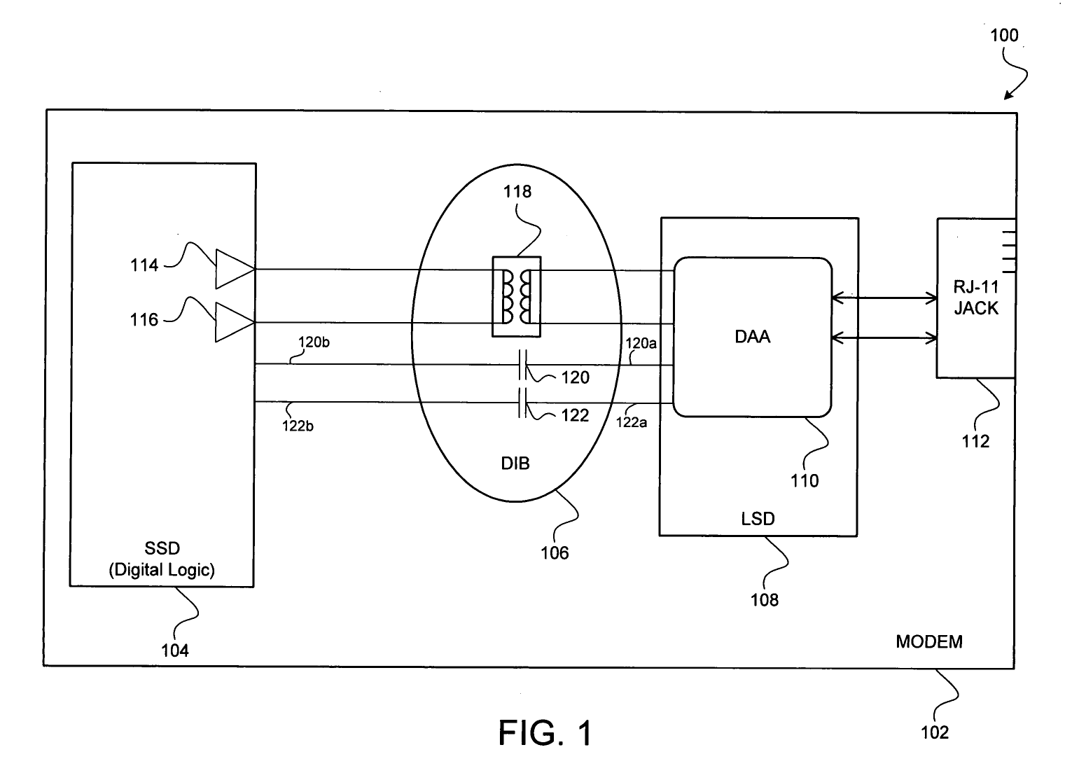

FIG. 1 shows an exemplary conventional digital isolation barrier (“DIB”) coupled to an exemplary data access arrangement (“DAA”) in an exemplary modem. It is noted that a modem is an example of a “telecommunications device” in the present application and the phrase “telecommunications device” includes a modem as well as any other type of communications device suitable for interfacing a computer to a telephone line. Certain details and features have been left out of FIG. 1, which are apparent to a person of ordinary skill in the art.

Diagram 100 in FIG. 1 includes modem 102 comprising system side device (“SSD”) 104 typically communicating with a computer (not shown), DIB 106, line side device (“LSD”) 108, DAA 110 and jack 112 utilized to electrically connect LSD 108 to a telephone line. Jack 112 can be, for example, an RJ-11 telephone line jack and can be used to connect modem 102 to a remote system such as a telephone network or a computer network, for example. As shown in FIG. 1, LSD 108 includes DAA 110, which is coupled to DIB 106. DIB 106 includes transformer 118 and capacitors 120 and 122. SSD 104 includes “power-clock drivers” 114 and 116.

As shown in FIG. 1, transformer 118 is situated in DIB 106; and on one side, transformer 118 is coupled to power-clock drivers 114 and 116 in SSD 104; while on the other side, transformer 118 is coupled to DAA 110 in LSD 108. DAA 110 in LSD 108 is coupled to jack 112. Power-clock drivers 114 and 116 can be used to transmit clock signals from SSD 104 to LSD 108 through transformer 118 in DIB 106. By way of example, power-clock drivers 114 and 116 can generate non-overlapping clock signals at a frequency of approximately 4 MHz. The clock signals also provide power from SSD 104 to LSD 108.

Also shown in FIG. 1, capacitors 120 and 122 are coupled between SSD 104 and DAA 110 in LSD 108. Capacitors 120 and 122 can be rated at approximately 1000 to 4000 volts and have a value of approximately 100 pico farads each, for example, and are used to isolate and help prevent various components in SSD 104 from being damaged by high voltage events in LSD 108 or at jack 112. However, capacitors 120 and 122 are susceptible to saturation and noise caused by voltage and power fluctuations occurring in LSD 108 or at jack 112. It is noted that in the conventional digital isolation barrier 106 discussed herein, capacitors 120 and 122 must have a very small value, for example, about 100 pico farads, as stated above. Due to the required small capacitance values for capacitors 120 and 122, the distance between SSD 104 and LSD 108 must be severely limited to avoid introducing parasitic capacitance which would significantly and undesirably add to the capacitance values of capacitors 120 and 122.

Data can be transmitted bi-directionally through capacitors 120 and 122, from SSD 104 to LSD 108, and from LSD 108 to SSD 104, in a manner known in the art, such as by “square wave modulation.” In “square wave modulation,” voltage difference between nodes 122a and 120a of capacitors 122 and 120, respectively; or alternatively, voltage difference between nodes 122b and 120b of capacitors 122 and 120, respectively, would result in a square wave corresponding to data being transmitted from SSD 104 or LSD 108. The duration of the lows and highs in the square wave indicate the data, i.e. the numbers of 0s and 1s in the data, being transmitted from SSD 104 or LSD 108. Thus, in the conventional digital isolation barrier scheme discussed in relation to FIG. 1, SSD 104 provides power and clock to LSD 108 through power-clock drivers 114 and 116, while bi-directional data transfer occurs through capacitors 120 and 122.

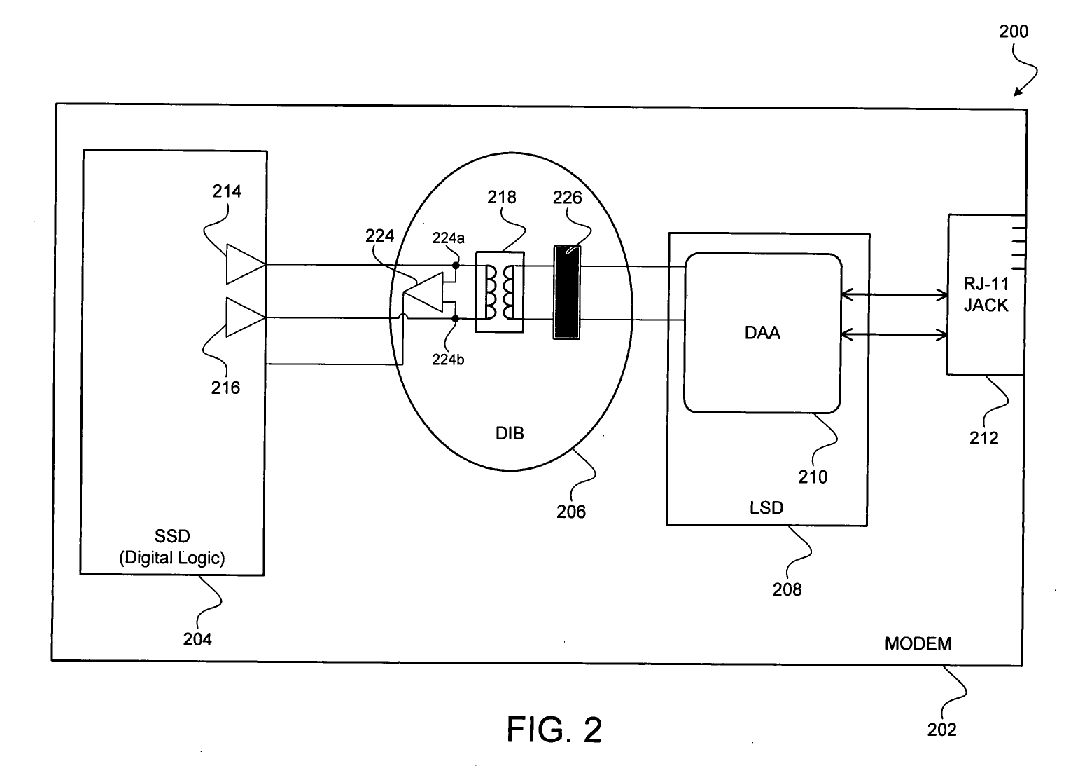

FIG. 2 shows a diagram of the present invention's digital isolation barrier 206 coupled to an exemplary DAA in an exemplary modem in accordance with one embodiment. Certain details and features have been left out of FIG. 2, which are apparent to a person of ordinary skill in the art.

Diagram 200 in FIG. 2 includes modem 202 comprising SSD 204, DIB 206, LSD 208, DAA 210 and jack 212. Jack 212 can be, for example, an RJ-11 telephone line jack and can be used to connect modem 202 to a remote device such as a telephone network or a computer network, for example. As shown in FIG. 2, LSD 208 includes DAA 210, which is coupled to DIB 206. DIB 206 includes transformer 218, comparator 224 and controlled impedance module 226. It is noted that although controlled impedance module 226 is shown as part of DIB 206, it (i.e. controlled impedance module 226) can be part of LSD 208, instead of DIB 206. Also shown in FIG. 2, SSD 204 includes power-clock drivers 214 and 216. Power-clock drivers 214 and 216 in SSD 204 are coupled to a first side of transformer 218.

As apparent from a comparison of the embodiment of the invention in FIG. 2 and the conventional technique of FIG. 1, capacitors 120 and 122 utilized for bi-directional data transfer in FIG. 1 are not utilized according to the present invention. Instead, data is transferred through transformer 218 in invention's DIB 206. According to one embodiment, data is transferred from SSD 204 to LSD 208, and vice versa, through a time division multiplexed (“TDM”) technique. In this technique, when SSD 204 is in the transmit mode and LSD 208 is in the receive mode, power-clock drivers 214 and 216 provide an amplitude modulated clock wave form conveying the data being transmitted from SSD 204 to LSD 208. In other words, the clock signals' amplitude is modulated according to the data being transmitted by SSD 204. The amplitude modulation takes place by a number of control lines, for example eight control lines, controlling the magnitude of the clock signal being outputted by each power-clock driver 214 and 216. Thus, the voltage difference between the high value in the square wave clock signal and the low value in the square wave clock signal outputted by each power-clock driver 214 and 216 corresponds to the data being transmitted from SSD 204 to LSD 208.

When SSD 204 is in the receive mode and LSD 208 is in the transmit mode, each power-clock driver 214 and 216 of SSD 204 transmits only unmodulated clock signals to provide clock and power to LSD 208. The unmodulated clock signals are amplitude modulated by LSD 208 through use of controlled impedance module 226. The amplitude modulation by LSD 208 is performed by varying the impedance of controlled impedance module 226, and thus by controlling the power consumption by module 226. Controlled impedance module 226 can be a variable impedance circuit, such as a transistor connected in series with a resistor. In this example, by controlling the bias conditions of the transistor, the impedance of module 226 is varied to achieve the desired impedance load on clock signals received from SSD 204. In other embodiments, controlled impedance module 226 can comprise a number of transistors and passive components to achieve a desired variable impedance load.

Thus, by varying the impedance of controlled impedance module 226, the clock signals received by LSD 208 are amplitude modulated according to the data that is desired to be transmitted from LSD 208 to SSD 204. In this mode, i.e. when SSD 204 is in the receive mode and LSD 208 is in the transmit mode, the amplitude modulated clock signals are detected and “demodulated” with the aid of comparator 224. Comparator 224 is designed to respond only when the difference in voltage between its two inputs 224a and 224b is greater than a certain pre-determined voltage. In this manner, comparator 224 is triggered only when modulated signals are received from LSD 208, and comparator 224 is not activated when unmodulated clock signals are present at inputs 224a and 224b.

Thus, in the manner described above, the present invention does not utilize capacitors, such as capacitors 120 and 122, for data transfer between line side device 208 and system side device 204. Instead, transformer 218 in digital isolation barrier 206, as well as controlled impedance module 226, are utilized to transmit data by amplitude modulated clock signals from system side device 204 to line side device 208 and vice versa.

Because the present invention uses a single path through transformer 218 to provide power, clock, and bi-directional data transfer, digital isolation barrier 206 is improved and a number of advantages are achieved. For example, since instead of capacitors a transformer is used for bi-directional data transfer, noise and ground voltage surges occurring in the line side device are substantially prevented from passing through to the system side device. Furthermore, capacitor saturation and data corruption do not occur. Moreover, the need for expensive capacitors having small capacitance values and high voltage ratings is eliminated, and production costs are reduced. Further, the line side device can be placed at a substantially greater distance away from the system side device, since the concern about adding to the capacitance of the data transfer capacitors is eliminated (because capacitors are no longer part of the data transfer mechanism). As such, systems based on the invention's digital isolation barrier can be designed with increased flexibility.

From the above description of the invention it is manifest that various techniques can be used for implementing the concepts of the present invention without departing from its scope. Moreover, while the invention has been described with specific reference to certain embodiments, a person of ordinary skill in the art would appreciate that changes can be made in form and detail without departing from the spirit and the scope of the invention. For example, controlled impedance module 226 can be placed inside LSD 208 instead of being placed inside DIB 206. Thus, the described embodiments are to be considered in all respects as illustrative and not restrictive. It should also be understood that the invention is not limited to the particular embodiments described herein but is capable of many rearrangements, modifications, and substitutions without departing from the scope of the invention.

Thus, isolation barrier for interfacing a line side device to a system side device has been described.

1. An isolation barrier coupled between a system side device and a line side device, said isolation barrier comprising a transformer and a controlled impedance module;
said system side device being configured to generate an amplitude modulated clock signal when said system side device is in a transmit mode, and being further configured to generate an unmodulated clock signal when said system side device is in a receive mode;
said controlled impedance module and said line side device being configured to cause said unmodulated clock signal to be amplitude modulated when said system side device is in said receive mode;
said transformer being configured to provide to said line side device said amplitude modulated clock signal generated by said system side device, and being further configured to provide to said system side device said clock signal amplitude modulated by said controlled impedance module and said line side device.

2. The isolation barrier of claim 1 wherein said isolation barrier further comprises a comparator, said comparator receiving said clock signal amplitude modulated by said controlled impedance module and said line said device, and said comparator outputting a demodulated clock signal to said system side device.

3. The isolation barrier of claim 1 wherein said system side device generates said amplitude modulated clock signal by a power-clock driver.

4. The isolation barrier of claim 1 wherein said system side device provides power to said line side device through said amplitude modulated clock signal when said system side device is in said transmit mode.

5. The isolation barrier of claim 1 wherein said system side device provides power to said line side device through said unmodulated clock signal.

6. The isolation barrier of claim 5 wherein said line side device causes said controlled impedance device to consume power from said unmodulated clock signal according to data being transmitted by said line side device.

7. The isolation barrier of claim 3 wherein said power-clock driver generates said amplitude modulated clock signal according to data being transmitted from said system side device.

8. The isolation barrier of claim 1 wherein said controlled impedance module comprises at least one transistor.

9. The isolation barrier of claim 1 wherein said transformer substantially prevents noise from said line side device to pass through to said system side device.

10. The isolation barrier of claim 1 wherein said transformer substantially prevents a line side device ground voltage change from causing a system side device ground voltage change.

11. A telecommunications device comprising:
a line side device for interfacing with a telephone line;
a system side device for interfacing with a computer;
an isolation barrier for coupling said line side device to said system side device, thereby causing data to be transmitted from said system side device to said line side device when said system side device is in a transmit mode, and causing data to be received by said system side device from said line side device when said system side device is in a receive mode.

12. The telecommunications device of claim 11 wherein said system side device generates an amplitude modulated clock signal when said system side device is in said transmit mode.

13. The telecommunications device of claim 11 wherein said system side device generates an unmodulated clock signal when said system side device is in said receive mode.

14. The telecommunications device of claim 13 wherein said line side device causes said unmodulated clock signal to be amplitude modulated when said system side device is in said receive mode.

15. The telecommunications device of claim 14 wherein said line side device utilizes a controlled impedance module in said isolation barrier for causing said unmodulated clock signal to be amplitude modulated when said system side device is in said receive mode.

16. The telecommunications device of claim 11 wherein said isolation barrier comprises a transformer configured to provide to said line side device an amplitude modulated clock signal generated by said system side device, and further configured to provide to said system side device a clock signal amplitude modulated by said line side device.

17. The telecommunications device of claim 11 further comprising a comparator, said comparator receiving a clock signal amplitude modulated by said line said device, and said comparator outputting a demodulated clock signal to said system side device.

18. The telecommunications device of claim 12 wherein said system side device generates said amplitude modulated clock signal by a power-clock driver.

19. The telecommunications device of claim 12 wherein said system side device provides power to said line side device through said amplitude modulated clock signal.

20. The telecommunications device of claim 13 wherein said system side device provides power to said line side device through said unmodulated clock signal.
